(19) United States
(12) Patent Application Publication
(10) Pub. No.: US 2025/0218713 A1
(43) Pub. Date: Jul. 3, 2025

(54) POWER SUPPLY CONTROL DEVICE, POWER SUPPLY CONTROL METHOD, AND COMPUTER PROGRAM

(71) Applicants: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(72) Inventors: Takeo UCHINO, Yokkaichi-shi, Mie (JP); Yuta TANINAKA, Yokkaichi-Shi, Mie (JP)

(73) Assignees: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(21) Appl. No.: 18/852,571

(22) PCT Filed: Apr. 3, 2023
(86) PCT No.: PCT/JP2023/013762

§ 371 Date: Sep. 30, 2024

(30) Foreign Application Priority Data
Apr. 4, 2022 (JP) 2022-062539

(51) Int. Cl. H01H 47/00; G01R 19/165; G01R 31/327

(52) U.S. Cl. CPC H01H 47/002; G01R 19/1659; G01R 31/3278

(57) ABSTRACT

A power supply control device controls power supply through a relay contact. A control unit (processing unit) in a microcomputer acquires a first voltage value of an NO terminal of the relay contact on a downstream side, if the relay contact is on. The control unit determines whether or not an abnormality occurs in the relay contact, based on the acquired first voltage value.

### CROSS-REFERENCE TO RELATED APPLICATIONS

This application is the U.S. national stage of PCT/JP2023/013762 filed on Apr. 3, 2023, which claims priority of Japanese Patent Application No. JP 2022-062539 filed on Apr. 4, 2022, the contents of which are incorporated herein.

### TECHNICAL FIELD

The present disclosure relates to a power supply control device, a power supply control method, and a computer program.

### BACKGROUND

JP 2013-169895A discloses a configuration of controlling the power supply from a DC power source to a load. A relay contact is connected between the positive electrode of the DC power source and one end of the load. The negative electrode of the DC power source and the other end of the load are grounded. The power supply from the DC power source to the load is controlled by switching the relay contact on or off.

A relay contact switches from off to on as a result of a conductor coming into contact with a terminal. The state thereof switches from on to off as a result of the conductor separating from the terminal. If the conductor or the terminal is deformed or worn, the flow of current through the relay contact may become unstable. As a result, it is possible that an abnormality occurs in the relay contact. JP 2013-169895A does not consider detection of an abnormality in the relay contact.

The present disclosure has been made in view of such circumstances, and has an object of providing a power supply control device, power supply control method, and computer program that can detect an abnormality in a relay contact.

### SUMMARY

A power supply control device according to an aspect of the present disclosure is a power supply control device configured to control power supply through a relay contact, including a processing unit configured to execute processing, wherein the processing unit is configured to: acquire a first voltage value at a downstream end of the relay contact, if the relay contact is on; and determine whether or not an abnormality occurs in the relay contact, based on the acquired first voltage value.

A power supply control method according to an aspect of the present disclosure is a power supply control method of controlling power supply through a relay contact, wherein a computer executes: a step of acquiring a first voltage value at a downstream end of the relay contact, if the relay contact is on; and a step of determining whether or not an abnormality occurs in the relay contact, based on the acquired first voltage value.

A computer program according to an aspect of the present disclosure is a computer program for causing a computer to execute: a step of acquiring a first voltage value at a downstream end of a relay contact through which a current flows, if the relay contact is on; and a step of determining whether or not an abnormality occurs in the relay contact, based on the acquired first voltage value.

Thus, the presently disclosed technique can be implemented not only as a power supply control device including the foregoing characteristic processing unit but also as a power supply control method including steps corresponding to the foregoing characteristic processing or as a computer program for causing a computer to execute these steps. The presently disclosed technique can also be implemented as a semiconductor integrated circuit that achieves the whole or part of the power supply control device or as a power system that includes the power supply control device.

### ADVANTAGEOUS EFFECTS

According to the above aspects, it is possible to detect an abnormality in a relay contact.

### BRIEF DESCRIPTION OF DRAWINGS

FIG. 1 is a block diagram showing main components of a power system in Embodiment 1.

FIG. 2 is a block diagram showing main components of a microcomputer.

FIG. 3 is a diagram showing a count threshold table and a count change table.

FIG. 4 is a flowchart showing the procedure of switching processing.

FIG. 5 is a flowchart showing the procedure of abnormality detection processing.

FIG. 6 is a flowchart showing the procedure of the abnormality detection processing.

FIG. 7 is a timing chart showing an example of the operation of the microcomputer.

FIG. 8 is a flowchart showing the procedure of abnormality detection processing in Embodiment 2.

### DETAILED DESCRIPTION OF PREFERRED EMBODIMENTS

First, embodiments of the present disclosure will be listed and described. The embodiments described below may be at least partly combined in any way.

A power supply control device according to an aspect of the present disclosure is a power supply control device configured to control power supply through a relay contact, including a processing unit configured to execute processing, wherein the processing unit is configured to: acquire a first voltage value at a downstream end of the relay contact, if the relay contact is on; and determine whether or not an abnormality occurs in the relay contact, based on the acquired first voltage value.

In the power supply control device according to an aspect of the present disclosure, the processing unit is configured to: repeatedly acquire the first voltage value during a predetermined period, if the relay contact is on; each time the first voltage value is acquired, determine whether the acquired first voltage value is outside a predetermined range; calculate a difference value between the first voltage value and one of an upper limit value and a lower limit value of the predetermined range that is closer to the first voltage value, if the first voltage value is determined to be outside the predetermined range; and determine that the abnormality occurs in the relay contact, if an integrated value of the difference value calculated during the predetermined period is greater than or equal to an integrated value threshold.

In the power supply control device according to an aspect of the present disclosure, the processing unit is configured to: repeatedly acquire the first voltage value during a predetermined period, if the relay contact is on; and determine that the abnormality occurs in the relay contact, if a number of first voltage values that are outside a predetermined range from among a plurality of first voltage values acquired during the predetermined period is greater than a predetermined number.

In the power supply control device according to an aspect of the present disclosure, the processing unit is configured to: acquire a second voltage value at an upstream end of the relay contact; and acquire the first voltage value, if the relay contact is on and the acquired second voltage value is greater than or equal to a predetermined voltage value.

In the power supply control device according to an aspect of the present disclosure, the processing unit is configured to: determine whether or not a switching count that is a number of times the relay contact has been switched on or off is greater than or equal to a count threshold; and lower the count threshold depending on an abnormality detection count that is a number of times the abnormality has been determined to occur in the relay contact.

In the power supply control device according to an aspect of the present disclosure, the relay contact is located in a power supply path from a DC power source to a load.

A power supply control method according to an aspect of the present disclosure is a power supply control method of controlling power supply through a relay contact, wherein a computer executes: a step of acquiring a first voltage value at a downstream end of the relay contact, if the relay contact is on; and a step of determining whether or not an abnormality occurs in the relay contact, based on the acquired first voltage value.

A computer program according to an aspect of the present disclosure is a computer program for causing a computer to execute: a step of acquiring a first voltage value at a downstream end of a relay contact through which a current flows, if the relay contact is on; and a step of determining whether or not an abnormality occurs in the relay contact, based on the acquired first voltage value.

With the power supply control device, power supply control method, and computer program according to the above aspects, a first voltage value is acquired if the relay contact is on, and an abnormality in the relay contact is detected based on the acquired first voltage value.

With the power supply control device according to the above aspect, a plurality of first voltage values are acquired during a predetermined period. If the acquired plurality of first voltage values include a first voltage value that is outside a predetermined range, the difference value (absolute value) between the first voltage value outside the predetermined range and the upper limit value or lower limit value of the predetermined range is calculated. If an integrated value of the difference value is greater than or equal to an integrated value threshold, an abnormality in the relay contact is detected.

With the power supply control device according to the above aspect, a plurality of first voltage values are acquired during a predetermined period. If the number of first voltage values that are outside a predetermined range from among the acquired plurality of first voltage values is greater than a predetermined number, an abnormality in the relay contact is detected.

With the power supply control device according to the above aspect, if a second voltage value is low, a first voltage value is not acquired because there is a possibility of erroneous determination being made.

With the power supply control device according to the above aspect, whether or not the switching count, i.e. the number of times the relay contact has been switched, is greater than or equal to a count threshold is determined. Based on this, notification can be made to replace the relay contact. The count threshold is lowered depending on the abnormality detection count. This accelerates the timing of notification to replace the relay contact.

With the power supply control device according to the above aspect, the power supply from the DC power source to the load is controlled by switching the relay contact on or off.

Specific examples of power systems according to embodiments of the present disclosure will be described below, with reference to the drawings. The present disclosure is not limited to these examples, but is defined by the claims and intended to include all modifications within the meaning and scope equivalent to the claims.

### Structure of Power System 1

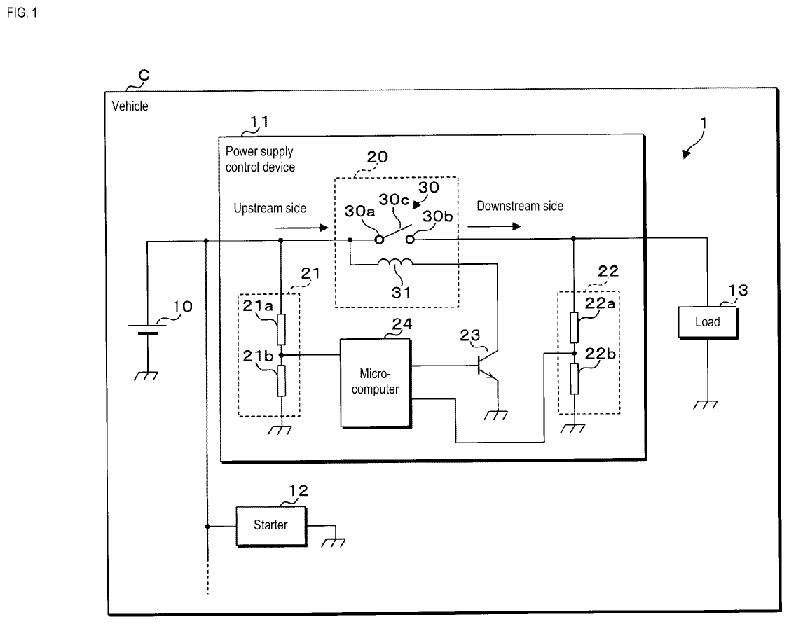

FIG. 1 is a block diagram showing main components of a power system 1 in Embodiment 1. The power system 1 is mounted on a vehicle C. The power system 1 includes a DC power source 10, a power supply control device 11, a starter 12, and a load 13. The DC power source 10 is, for example, a battery. The load 13 is, for example, an electronic control unit (ECU).

The power supply control device 11 includes a relay 20. The relay 20 includes a relay contact 30 and a coil 31. The relay contact 30 includes a COM terminal 30a, an NO terminal 30b, and a rod-shaped conductor 30c. One end of the conductor 30c is connected to the COM terminal 30a. The conductor 30c is capable of rotating about the COM terminal 30a.

The conductor 30c is pulled by a spring (not shown). When no current flows through the coil 31, the conductor 30c is separated from the NO terminal 30b by the spring. In this state, no current flows through the COM terminal 30a and the NO terminal 30b. The relay contact 30 is off. When a current flows through the coil 31, the coil 31 acts as a magnet and attracts the conductor 30c toward the NO terminal 30b. As a result, the conductor 30c comes into contact with the NO terminal 30b. This allows a current to flow through the COM terminal 30a and the NO terminal 30b. The relay contact 30 is on.

The negative electrode of the DC power source 10 is grounded. For example, grounding is achieved by connection to the body of the vehicle C. The positive electrode of the DC power source 10 is connected to the COM terminal 30a of the relay contact 30 and one end of the starter 12. The NO terminal 30b of the relay contact 30 is connected to one end of the load 13. The other end of the load 13 is grounded. The other end of the starter 12 is grounded.

The power supply control device 11 switches the relay contact 30 from off to on. This causes a current to flow from the positive electrode of the DC power source 10 to the relay contact 30, the load 13, and the negative electrode of the DC power source 10 in this order as indicated by the arrows. As a result, power is supplied to the load 13. The power supply control device 11 switches the relay contact 30 from on to off. This stops the flow of current through the relay contact 30, as a result of which the power supply to the load 13 is stopped. The power supply control device 11 thus controls the power supply from the DC power source 10 to the load 13 by switching the relay contact 30 on or off.

When the relay contact 30 is on, the current flows through the COM terminal 30a, the conductor 30c, and the NO terminal 30b in this order in the relay contact 30. The COM terminal 30a corresponds to the upstream end of the relay contact 30. The NO terminal 30b corresponds to the downstream end of the relay contact 30. Since the current flows from the positive electrode of the DC power source 10 to the relay contact 30 and the load 13 in this order as mentioned above, the relay contact 30 is located in the power supply path from the DC power source to the load 13.

The positive electrode of the DC power source 10 is also connected to one end of one or more vehicle-mounted devices. The other end of the one or more vehicle-mounted devices is grounded. The DC power source 10 supplies power to not only the load 13 but also the starter 12 and the one or more vehicle-mounted devices. The starter 12 is a motor for starting the engine of the vehicle C. In the DC power source 10, the current flows from the power source body through an internal resistor. The voltage drop caused by the internal resistor is larger when the current value of the current flowing through the internal resistor is larger.

The voltage value of the positive electrode of the DC power source 10 is referred to as a power source voltage value. The reference potential of the power source voltage value is the ground potential. Since the positive electrode of the DC power source 10 is connected to the COM terminal 30a of the relay contact 30, the power source voltage value is the voltage value of the COM terminal 30a, which corresponds to a second voltage value.

The power source voltage value is the voltage value of the output terminal of the internal resistor from which the current is output. The power source voltage value is lower when the current value of the current flowing through the internal resistor is larger. When the starter 12 operates, the current value of the current flowing through the internal resistor is large. Therefore, when the starter 12 operates, the power source voltage value decreases greatly. When the starter 12 stops operation, the power source voltage value returns to the value before the operation of the starter 12.

The current value of the current flowing through the internal resistor does not fluctuate greatly due to the operation of the one or more vehicle-mounted devices. Therefore, the power source voltage value is stable regardless of whether the one or more vehicle-mounted devices are in operation or not.

### Structure of Power Supply Control Device 11

The power supply control device 11 includes a power source voltage detection circuit 21, an output voltage detection circuit 22, a transistor 23, and a microcomputer 24, in addition to the relay 20. The power source voltage detection circuit 21 includes voltage dividing resistors 21a and 21b. The output voltage detection circuit 22 includes voltage dividing resistors 22a and 22b. The transistor 23 is an NPN-type bipolar transistor.

One end of the voltage dividing resistor 21a of the power source voltage detection circuit 21 is connected to the COM terminal 30a of the relay contact 30. The other end of the voltage dividing resistor 21a is connected to one end of the voltage dividing resistor 21b. The other end of the voltage dividing resistor 21b is grounded. The connection node between the two voltage dividing resistors 21a and 21b is connected to the microcomputer 24. The two voltage dividing resistors 21a and 21b divide the voltage output from the positive electrode of the DC power source 10. The voltage value of the voltage output from the positive electrode of the DC power source 10 is the power source voltage value. The power source voltage detection circuit 21 outputs the voltage value of the divided voltage obtained by the voltage division by the two voltage dividing resistors 21a and 21b to the microcomputer 24 as analog power source voltage information indicating the power source voltage value. The power source voltage information is a value obtained by dividing the power source voltage value by a constant value, and is proportional to the power source voltage value.

One end of the voltage dividing resistor 22a of the output voltage detection circuit 22 is connected to the NO terminal 30b of the relay contact 30. The other end of the voltage dividing resistor 22a is connected to one end of the voltage dividing resistor 22b. The other end of the voltage dividing resistor 22b is grounded. The connection node between the two voltage dividing resistors 22a and 22b is connected to the microcomputer 24. The voltage value of the NO terminal 30b is referred to as an output voltage value. The output voltage value is a voltage value whose reference potential is the ground potential. The output voltage value corresponds to a first voltage value.

The two voltage dividing resistors 22a and 22b divide the voltage of the NO terminal 30b. The output voltage detection circuit 22 outputs the voltage value of the divided voltage obtained by the voltage division by the two voltage dividing resistors 22a and 22b to the microcomputer 24 as analog output voltage information indicating the output voltage value. The output voltage information is a value obtained by dividing the output voltage value by a constant value, and is proportional to the output voltage value.

In the relay 20, one end of the coil 31 is connected to the COM terminal 30a. The other end of the coil 31 is connected to the collector of the transistor 23. The emitter of the transistor 23 is grounded. The base of the transistor 23 is connected to the microcomputer 24. The transistor 23 functions as a switch. The microcomputer 24 switches the transistor 23 on or off by adjusting the voltage value of the base relative to the ground potential. When the transistor 23 is on, a current can flow through the collector and the emitter in this order. When the transistor 23 is off, no current flows through the collector and the emitter.

When the transistor 23 is off, no current flows through the coil 31. Therefore, the relay contact 30 is off. When the microcomputer 24 switches the transistor 23 from off to on, a current flows from the positive electrode of the DC power source 10 to the coil 31, the transistor 23, and the negative electrode of the DC power source 10 in this order. Since the current flows through the coil 31, the relay contact 30 is switched from off to on. When the microcomputer 24 switches the transistor 23 from on to off, the flow of current through the coil 31 stops. Therefore, the relay contact 30 is switched off. Thus, the microcomputer 24 switches the relay contact 30 on or off by switching the transistor 23 on or off.

### Configuration of Microcomputer 24

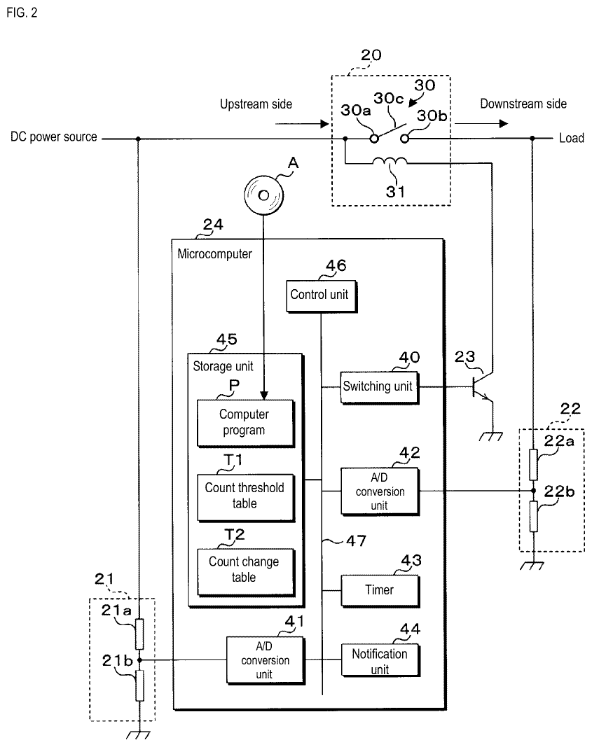

FIG. 2 is a block diagram showing main components of the microcomputer 24. The microcomputer 24 includes a switching unit 40, A/D conversion units 41 and 42, a timer 43, a notification unit 44, a storage unit 45, and a control unit 46. These components are connected to an internal bus 47. The switching unit 40 is also connected to the base of the transistor 23. The A/D conversion unit 41 is also connected to the connection node between the two voltage dividing resistors 21a and 21b. The A/D conversion unit 42 is also connected to the connection node between the two voltage dividing resistors 22a and 22b.

The switching unit 40 switches the transistor 23 on or off by adjusting the voltage of the base of the transistor 23 whose reference potential is the ground potential. The control unit 46 instructs the switching unit 40 to switch the transistor 23 on or off.

The A/D conversion unit 41 receives input of analog power source voltage information from the power source voltage detection circuit 21. The A/D conversion unit 41 converts the analog power source voltage information input from the power source voltage detection circuit 21 into digital power source voltage information. The power source voltage information converted by the A/D conversion unit 41 is acquired by the control unit 46. The power source voltage value indicated by the power source voltage information acquired by the control unit 46 substantially matches the power source voltage value at the time of acquisition.

The A/D conversion unit 42 receives input of analog output voltage information from the output voltage detection circuit 22. The A/D conversion unit 42 converts the analog output voltage information input from the output voltage detection circuit 22 into digital output voltage information. The output voltage information converted by the A/D conversion unit 42 is acquired by the control unit 46. The output voltage value indicated by the output voltage information acquired by the control unit 46 substantially matches the output voltage value at the time of acquisition.

The timer 43 starts and ends measuring time according to instructions from the control unit 46. The time measured by the timer 43 is read by the control unit 46.

The notification unit 44 makes notification according to instructions from the control unit 46. Specifically, the notification unit 44 makes notification to replace the relay 20 by lighting a lamp or displaying a message. The notification unit 44 may make notification by transmitting data indicating to replace the relay 20.

The storage unit 45 is composed of, for example, volatile memory and non-volatile memory. The storage unit 45 stores a computer program P. The control unit 46 includes a processing element that executes processing, such as a central processing unit (CPU). The control unit 46 functions as the processing unit. The control unit 46 executes the computer program P to execute switching processing, abnormality detection processing, etc. in parallel.

The switching processing is processing of switching the relay contact 30 on or off. In the switching processing, the control unit 46 determines whether or not the switching count, i.e. the number of times the relay contact 30 has been switched on or off, is greater than or equal to a count threshold. If the switching count is greater than or equal to the count threshold, the control unit 46 causes the notification unit 44 to make notification. The abnormality detection processing is processing of detecting an abnormality in the relay contact 30. In the abnormality detection processing, the control unit 46 lowers the count threshold depending on the abnormality detection count, i.e. the number of times an occurrence of an abnormality in the relay contact 30 has been determined.

If the NO terminal 30b or the conductor 30c of the relay contact 30 is deformed or worn, the flow of current through the relay contact 30 becomes unstable. An abnormality in the relay contact 30 is a phenomenon that the flow of current is unstable. When an abnormality occurs while the relay contact 30 is on, the output voltage value of the NO terminal 30b fluctuates greatly.

The computer program P may be provided to the microcomputer 24 using a non-transitory storage medium A that stores the computer program P in a readable manner. The storage medium A is, for example, a portable memory. Examples of the portable memory include CD-ROM, a Universal Serial Bus (USB) memory, an SD card, a micro SD card, and CompactFlash®. If the storage medium A is a portable memory, the processing element in the control unit 46 may read the computer program P from the storage medium A using a reading device (not shown). The read computer program P is then written to the storage unit 45. The computer program P may be provided to the microcomputer 24 by a communication unit (not shown) in the microcomputer 24 communicating with an external device. In this case, the processing element in the microcomputer 24 acquires the computer program P through the communication unit. The acquired computer program P is then written to the storage unit 45.

The number of processing elements included in the control unit 46 is not limited to one, and may be two or more. If the control unit 46 includes a plurality of processing elements, the plurality of processing elements may execute the switching processing, the abnormality detection processing, etc. in cooperation.

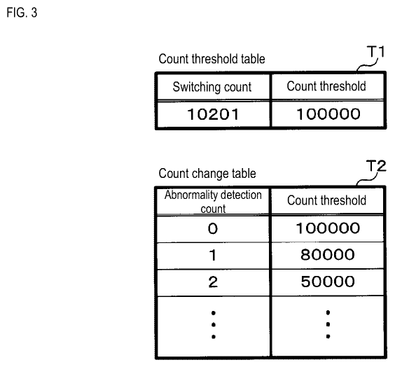

The storage unit 45 includes a count threshold table T1 indicating a count threshold, and a count change table T2 used when the count threshold is to be changed. FIG. 3 is a diagram showing the count threshold table T1 and the count change table T2. The count threshold table T1 indicates the switching count, i.e. the number of times the relay contact 30 has been switched on or off by the switching unit 40, and the count threshold. The switching count and the count threshold are each changed by the control unit 46. In the example in FIG. 3, the count threshold is 100000 and the switching count is 10201.

The count change table T2 indicates a plurality of count thresholds corresponding to a plurality of abnormality detection counts. In the example in FIG. 3, if the abnormality detection count is 0, the count threshold is 100000. If the abnormality detection count is 1, the count threshold is 80000. If the abnormality detection count is 2, the count threshold is 50000. The count threshold is smaller when the abnormality detection count is larger.

### Switching Processing

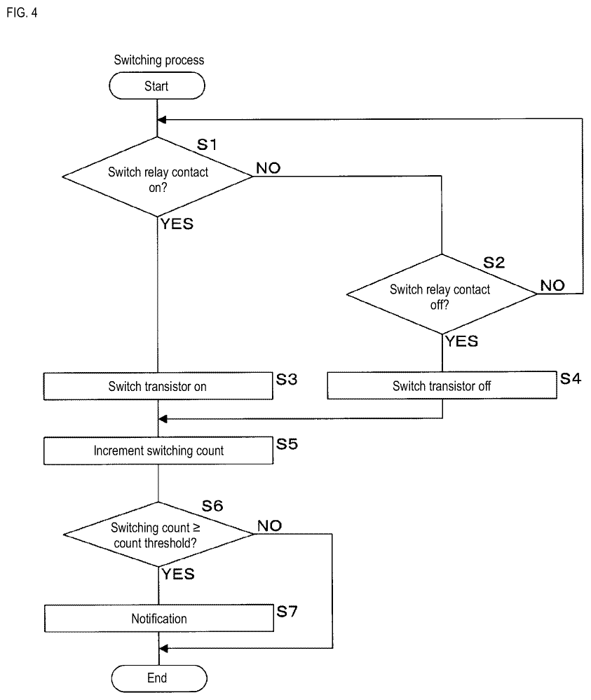

FIG. 4 is a flowchart showing the procedure of the switching processing. In the switching processing, the control unit 46 first determines whether or not the relay contact 30 is to be switched on (step S1). The microcomputer 24 includes, for example, an on signal receiving unit to which an on signal instructing to switch the relay contact 30 on is input. With this structure, if an on signal is input to the on signal receiving unit, the control unit 46 determines to switch the relay contact 30 on. If an on signal is not input to the on signal receiving unit, the control unit 46 determines not to switch the relay contact 30 on.

If the control unit 46 determines not to switch the relay contact 30 on (S1: NO), the control unit 46 determines whether to switch the relay contact 30 off (step S2). The microcomputer 24 includes, for example, an off signal receiving unit to which an off signal instructing to switch the relay contact 30 off is input. With this structure, if an off signal is input to the off signal receiving unit, the control unit 46 determines to switch the relay contact 30 off. If an off signal is not input to the off signal receiving unit, the control unit 46 determines not to switch the relay contact 30 off.

If the control unit 46 determines not to switch the relay contact 30 off (S2: NO), the control unit 46 executes step S1 again. The control unit 46 waits until the timing of switching the relay contact 30 on or off. If the control unit 46 determines to switch the relay contact 30 on (S1: YES), the control unit 46 instructs the switching unit 40 to switch the transistor 23 on (step S3). This causes a current to flow through the coil 31, as a result of which the relay contact 30 is switched on. The DC power source 10 supplies power to the load 13 through the relay contact 30.

If the control unit 46 determines to switch the relay contact 30 off (S2: YES), the control unit 46 instructs the switching unit 40 to switch the transistor 23 off (step S4). This stops the flow of current through the coil 31, as a result of which the relay contact 30 is switched off. The power supply from the DC power source 10 to the load 13 is thus stopped.

After step S3 or S4, the control unit 46 increments the switching count indicated in the count threshold table T1 by 1 (step S5). If step S5 is executed when the switching count is 10201 as shown in FIG. 3, the control unit 46 changes the switching count to 10202. After step S5, the control unit 46 determines whether or not the switching count is greater than or equal to the count threshold in the count threshold table T1 (step S6).

If the control unit 46 determines that the switching count is greater than or equal to the count threshold (S6: YES), the control unit 46 instructs the notification unit 44 to make notification (step S7). Consequently, replacement of the relay 20 is notified to the user of the power supply control device 11, prompting the user to replace the relay 20. If the control unit 46 determines that the switching count is less than the count threshold (S6: NO) or after step S7, the control unit 46 ends the switching processing. After ending the switching processing, the control unit 46 executes the switching processing again.

As described above, in the switching processing, the user of the power supply control device 11 is prompted to replace the relay 20 if the switching count is greater than or equal to the count threshold.

### Abnormality Detection Processing

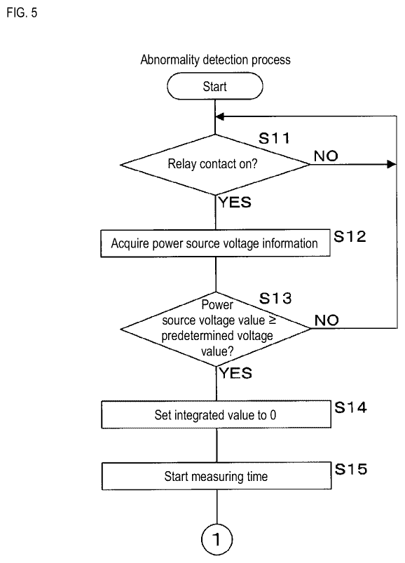

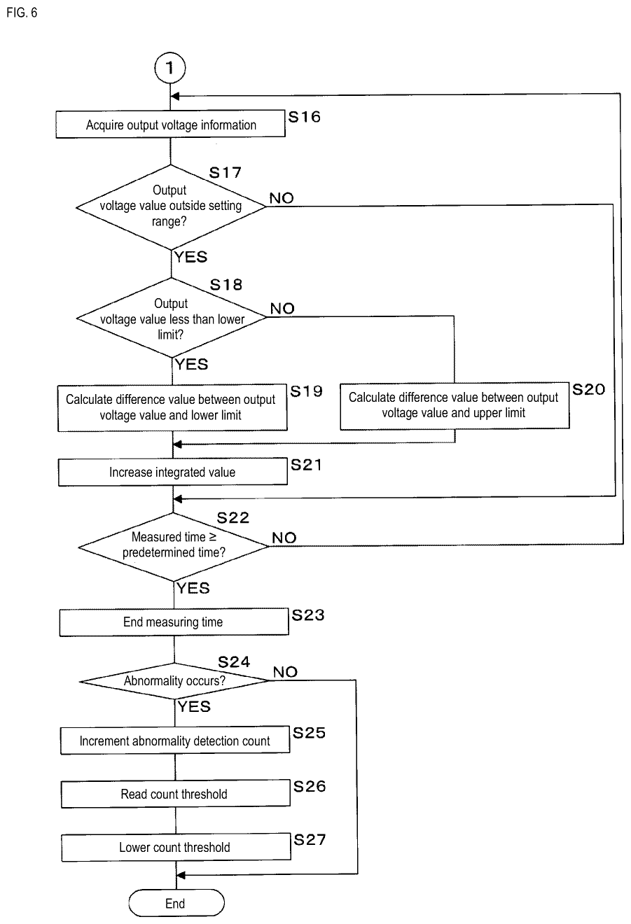

FIGS. 5 and 6 are flowcharts showing the procedure of the abnormality detection processing. In the abnormality detection processing, the difference value related to the output voltage value is integrated. The storage unit 45 stores integration data indicating the integrated value of the difference value. The integrated value indicated by the integration data is changed by the control unit 46. The storage unit 45 stores count data indicating the abnormality detection count. The abnormality detection count indicated by the count data is changed by the control unit 46. Upon manufacture of the power supply control device 11 or upon replacement of the relay 20, the abnormality detection count indicated by the count data is set to 0.

The control unit 46 first determines whether or not the relay contact 30 is on (step S11). If the relay contact 30 is not on, the relay contact 30 is off. If the control unit 46 determines that the relay contact 30 is not on (S11: NO), the control unit 46 executes step S11 again and waits until the relay contact 30 is switched on.

If the control unit 46 determines that the relay contact 30 is on (S11: YES), the control unit 46 acquires power source voltage information from the A/D conversion unit 41 (step S12). Since the power source voltage information indicates the power source voltage value, acquiring the power source voltage information corresponds to acquiring the power source voltage value. The control unit 46 then determines whether or not the power source voltage value indicated by the power source voltage information acquired in step S12 is greater than or equal to a predetermined voltage value (step S13). The predetermined voltage value is a preset constant value. If the control unit 46 determines that the power source voltage value is less than the predetermined voltage value (S13: NO), the control unit 46 executes step S11 again. The control unit 46 waits until the power source voltage value becomes greater than or equal to the predetermined voltage value when the relay contact 30 is on.

If the control unit 46 determines that the power source voltage value is greater than or equal to the predetermined voltage value (S13: YES), the control unit 46 sets the integrated value indicated by the integration data to 0 (step S14) and instructs the timer 43 to start measuring time (step S15).

After step S15, the control unit 46 acquires output voltage information from the A/D conversion unit 42 (step S16). Since the output voltage information indicates the output voltage value, acquiring the output voltage information corresponds to acquiring the output voltage value. The control unit 46 then determines whether or not the output voltage value indicated by the output voltage information acquired in step S16 is outside a preset setting range (step S17). The setting range corresponds to a predetermined range. If the control unit 46 determines that the output voltage value is outside the setting range (S17: YES), the control unit 46 determines whether or not the output voltage value indicated by the output voltage information acquired in step S16 is less than a lower limit value of the setting range (step S18). In step S18, if the output voltage value is not less than the lower limit value of the setting range, the output voltage value is greater than an upper limit value of the setting range.

If the control unit 46 determines that the output voltage value is less than the lower limit value (S18: YES), the control unit 46 calculates the difference value between the output voltage value and the lower limit value (step S19). If the control unit 46 determines that the output voltage value is not less than the lower limit value (S18: NO), the control unit 46 calculates the difference value between the output voltage value and the upper limit value (step S20). In steps S19 and S20, the output voltage value is the output voltage value indicated by the output voltage information acquired in step S16. The upper limit value and the lower limit value are respectively the upper limit value and lower limit value of the setting range. The difference value is an absolute value.

After step S19 or S20, the control unit 46 increases the integrated value indicated by the integration data by the difference value calculated in step S19 or S20 (step S21). The integrated value is calculated based on the difference value. The difference value is calculated based on the output voltage value. The integrated value is therefore a value based on the output voltage value. If the output voltage value is not outside the setting range (S17: NO) or after step S21, the control unit 46 determines whether or not the time measured by the timer 43 is greater than or equal to a predetermined time (step S22). The predetermined time is a preset constant value.

If the control unit 46 determines that the measured time is less than the predetermined time (S22: NO), the control unit 46 executes step S16 again. The control unit 46 repeatedly acquires output voltage information (output voltage value) until the measured time reaches greater than or equal to the predetermined time. If the output voltage value is outside the setting range, the control unit 46 increases the integrated value indicated by the integration data by the difference value.

If the relay contact 30 is switched from on to off before the measured time reaches greater than or equal to the predetermined time, the control unit 46 instructs the timer 43 to end measuring time. The control unit 46 then executes the abnormality detection process again.

If the control unit 46 determines that the measured time is greater than or equal to the predetermined time (S22: YES), the control unit 46 instructs the timer 43 to end measuring time (step S23). After step S23, the control unit 46 determines whether or not an abnormality occurs in the relay contact 30 (step S24). In step S24, the control unit 46 determines that an abnormality occurs if the integrated value indicated by the integration data is greater than or equal to an integrated value threshold. The control unit 46 determines that no abnormality occurs if the integrated value indicated by the integration data is less than the integrated value threshold. The integrated value threshold is a preset constant positive value. If the control unit 46 determines that an abnormality occurs (S24: YES), the control unit 46 increments the abnormality detection count indicated by the count data by 1 (step S25).

Next, the control unit 46 reads the count threshold corresponding to the abnormality detection count indicated by the count data from the count change table T2 (step S26). The control unit 46 then lowers the count threshold indicated in the count threshold table T1 to the count threshold read in step S26 (step S27). In the count change table T2, the count threshold is smaller when the abnormality detection count is larger. Therefore, the count threshold in the count threshold table T1 is lowered as a result of step S27. The timing of notification to replace the relay 20 is accelerated as a result of step S27. If the control unit 46 determines that no abnormality occurs (S24: NO) or after step S27, the control unit 46 ends the abnormality detection processing. After ending the abnormality detection processing, the control unit 46 executes the abnormality detection processing again.

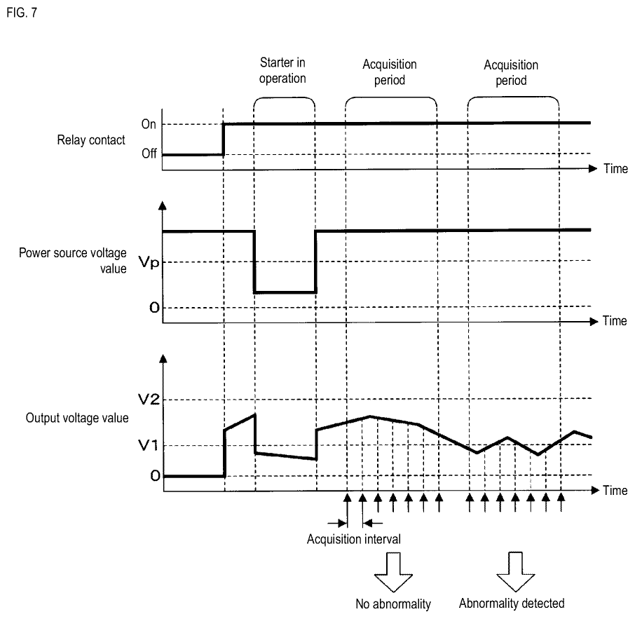

FIG. 7 is a timing chart showing an example of the operation of the microcomputer 24. FIG. 7 shows changes of the state of the relay contact 30, changes of the power source voltage value, and changes of the output voltage value. The horizontal axis of each of the three graphs represents time. In FIG. 7, Vp denotes the predetermined voltage value. V1 and V2 denote the upper limit value and lower limit value of the setting range respectively. The “acquisition period” is a period from when the timer 43 starts measuring time until the time measured by the timer 43 reaches the predetermined time. The acquisition period corresponds to the predetermined period.

As mentioned above, if the relay contact 30 is off or if the power source voltage value is less than the predetermined voltage value Vp, the control unit 46 does not acquire output voltage information. The predetermined voltage value Vp is less than or equal to the power source voltage value when the starter 12 is not in operation. The predetermined voltage value Vp is greater than the power source voltage value when the starter 12 is in operation. Thus, while the starter 12 is in operation, the power source voltage value is less than the predetermined voltage value Vp, so that the control unit 46 does not acquire output voltage information.

If the relay contact 30 is on and the power source voltage value indicated by the acquired power source voltage information is greater than or equal to the predetermined voltage value, the control unit 46 causes the timer 43 to start measuring time to thus start the acquisition period. The control unit 46 repeatedly acquires output voltage information (output voltage value) during the acquisition period. The acquisition intervals at which the control unit 46 acquires output voltage information during the acquisition period are constant. Each time the control unit 46 acquires output voltage information, the control unit 46 determines whether or not the output voltage value indicated by the acquired output voltage information is outside the setting range. If the control unit 46 determines that the output voltage value is outside the setting range, the control unit 46 calculates the difference value between the output voltage value and one of the upper limit value and lower limit value of the setting range that is closer to the output voltage value.

If the control unit 46 does not calculate any difference value during the acquisition period, the integrated value is 0, which is less than the integrated value threshold. The control unit 46 accordingly determines that no abnormality occurs in the relay contact 30. If the number of output voltage values that are outside the setting range from among the plurality of output voltage values acquired by the control unit 46 during the predetermined period is 1, the integrated value matches the difference value calculated using the output voltage value that is outside the setting range. If the number of output voltage values that are outside the setting range from among the plurality of output voltage values acquired by the control unit 46 during the predetermined period is 2 or more, the control unit 46 calculates an integrated value of difference values based on the two or more output voltage values. If the integrated value is greater than or equal to the integrated value threshold, the control unit 46 determines that an abnormality occurs in the relay contact 30, and detects an abnormality in the relay contact 30.

If the relay contact 30 is on and the power source voltage value indicated by the acquired power source voltage information is greater than or equal to the predetermined voltage value, the acquisition period is started repeatedly, as shown in FIG. 7. In the example in FIG. 7, in the first acquisition period, all output voltage values acquired by the control unit 46 are within the setting range, so that the integrated value is 0. The control unit 46 accordingly determines that no abnormality occurs in the relay contact 30. In the second acquisition period, the plurality of output voltage values acquired by the control unit 46 during the predetermined period include output voltage values that are outside the setting range and the integrated value is greater than the integrated value threshold, so that the control unit 46 detects an abnormality in the relay contact 30.

Even when the relay contact 30 is on, if the power source voltage value is less than the predetermined voltage value, there is a possibility of erroneous determination being made regarding abnormality. Accordingly, the control unit 46 does not acquire output voltage information (output voltage value). If the NO terminal 30b or the conductor 30c of the relay contact 30 is deformed or worn, the resistance value between the COM terminal 30a and the NO terminal 30b when the relay contact 30 is on may decrease. In this case, the output voltage value exceeds the upper limit of the setting range.

### Embodiment 2

In Embodiment 1, the control unit 46 in the microcomputer 24 determines whether or not an abnormality occurs in the relay contact 30 based on the integrated value. The value used to determine whether or not an abnormality occurs is, however, not limited to the integrated value.

The differences of Embodiment 2 from Embodiment 1 will be described below. Since the components other than those described below are the same as in Embodiment 1, the same components as in Embodiment 1 are given the same reference numerals and their description will be omitted.

### Abnormality Detection Processing

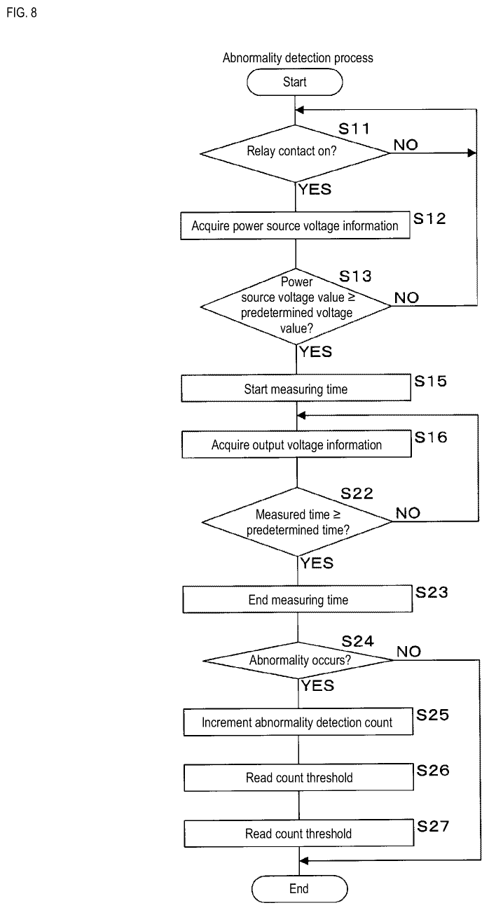

FIG. 8 is a flowchart showing the procedure of abnormality detection processing in Embodiment 2. In the abnormality detection processing in Embodiment 2, the control unit 46 in the microcomputer 24 executes steps S11 to S13, S15, S16, and S22 to S27 as in Embodiment 1. Step S24 in the abnormality detection processing in Embodiment 2 is different from that in the abnormality detection processing in Embodiment 1. Detailed description of steps S11 to S13, S15, S16, S22, S23, and S25 to S27 will accordingly be omitted.

In the abnormality detection processing in Embodiment 2, if the control unit 46 determines that the power source voltage value indicated by the power source voltage information acquired in step S12 is greater than or equal to the predetermined voltage value (S13: YES), the control unit 46 executes step S15. After step S16, the control unit 46 executes step S22. Therefore, if the relay contact 30 is on and the power source voltage value is greater than or equal to the predetermined voltage value, the control unit 46 repeatedly acquires output voltage information (output voltage value) until the time measured by the timer 43 reaches greater than or equal to the predetermined time. As described in Embodiment 1, the period until the time measured by the timer 43 reaches the predetermined time from 0 is the acquisition period.

After step S23, the control unit 46 determines whether or not an abnormality occurs in the relay contact 30 (step S24), as in Embodiment 1. In step S24 in Embodiment 2, the control unit 46 determines that an abnormality occurs in the relay contact 30 if the number of output voltage values that are outside the setting range from among the plurality of output voltage values indicated by the plurality of pieces of output voltage information acquired during the acquisition period is greater than or equal to a predetermined number. The control unit 46 determines that no abnormality occurs in the relay contact 30 if the number of output voltage values that are outside the setting range from among the plurality of output voltage values indicated by the plurality of pieces of output voltage information acquired during the acquisition period is less than the predetermined number. The predetermined number is a preset constant positive value.

If the control unit 46 determines that an abnormality occurs in the relay contact 30 (S24: YES), the control unit 46 executes steps S25 to S27 in sequence. Thus, the control unit 46 increments the abnormality detection count indicated by the count data by 1. The control unit 46 lowers the count threshold in the count threshold table T1 depending on the changed abnormality detection count.

After step S26 or if the control unit 46 determines that no abnormality occurs in the relay contact 30 (S24: NO), the control unit 46 ends the abnormality detection processing. After ending the abnormality detection process, the control unit 46 executes the abnormality detection processing again.

As described above, the control unit 46 acquires a plurality of output voltage values during the acquisition period. If the number of output voltage values that are outside the setting range from among the acquired plurality of output voltage values is greater than the predetermined number, the control unit 46 detects an abnormality in the relay contact 30. In the example in FIG. 7, in the first acquisition period, the number of output voltage values that are outside the setting range is 0, so that the control unit 46 detects no abnormality. In the second acquisition period, the number of output voltage values that are outside the setting range is 4. If the predetermined number is set to a value less than or equal to 4, the control unit 46 detects an abnormality. If the predetermined number is set to a value greater than 4, the control unit 46 detects no abnormality.

### Effects of Power Supply Control Device 11

The power supply control device 11 in Embodiment 2 has the same effects as the power supply control device 11 in Embodiment 1, except for the effect achieved by detecting an abnormality using an integrated value.

### Modifications

In Embodiments 1 and 2, as long as the transistor 23 functions as a switch that can be switched on or off by the switching unit 40 in the microcomputer 24, the transistor 23 is not limited to an NPN-type bipolar transistor and may be, for example, an N-channel field effect transistor (FET). Moreover, in the relay contact 30, the end of the conductor 30c may be connected to not the COM terminal 30a but the NO terminal 30b. In this case, the conductor 30c is capable of rotating about the NO terminal 30b. When no current flows through the coil 31, the conductor 30c is separated from the COM terminal 30a by a spring. In this state, the relay contact 30 is off. When a current flows through the coil 31, the conductor 30c is in contact with the COM terminal 30a. In this state, the relay contact 30 is on.

The technical features (constituent elements) described in Embodiments 1 and 2 can be combined with each other, and such combinations can form new technical features.

Embodiments 1 and 2 disclosed herein are illustrative and not restrictive in all respects. The scope of the present disclosure is defined by the claims, and not the meaning described above, and is intended to include all modifications within the meaning and scope equivalent to the claims.

The claims described in the CLAIMS can be combined with each other regardless of the form of reference. In the CLAIMS, multiple dependent claims that depend from a plurality of claims may be described. Multiple dependent claims that depend from multiple dependent claims may be described. Even if multiple dependent claims that depend from multiple dependent claims are not described, this does not limit the description of multiple dependent claims that depend from multiple dependent claims.

1. A power supply control device configured to control power supply through a relay contact, the power supply control device comprising
a processing unit configured to execute processing,
wherein the processing unit is configured to:
acquire a first voltage value at a downstream end of the relay contact, if the relay contact is on; and
determine whether or not an abnormality occurs in the relay contact, based on the acquired first voltage value.

2. The power supply control device according to claim 1, wherein the processing unit is configured to:
repeatedly acquire the first voltage value during a predetermined period, if the relay contact is on;
each time the first voltage value is acquired, determine whether the acquired first voltage value is outside a predetermined range;
calculate a difference value between the first voltage value and one of an upper limit value and a lower limit value of the predetermined range that is closer to the first voltage value, if the first voltage value is determined to be outside the predetermined range; and
determine that the abnormality occurs in the relay contact, if an integrated value of the difference value calculated during the predetermined period is greater than or equal to an integrated value threshold.

3. The power supply control device according to claim 1, wherein the processing unit is configured to:
repeatedly acquire the first voltage value during a predetermined period, if the relay contact is on; and
determine that the abnormality occurs in the relay contact, if a number of first voltage values that are outside a predetermined range from among a plurality of first voltage values acquired during the predetermined period is greater than a predetermined number.

4. The power supply control device according to claim 1, wherein the processing unit is configured to:
acquire a second voltage value at an upstream end of the relay contact; and
acquire the first voltage value, if the relay contact is on and the acquired second voltage value is greater than or equal to a predetermined voltage value.

5. The power supply control device according to claim 1, wherein the processing unit is configured to:
determine whether or not a switching count that is a number of times the relay contact has been switched on or off is greater than or equal to a count threshold; and
lower the count threshold depending on an abnormality detection count that is a number of times the abnormality has been determined to occur in the relay contact.

6. The power supply control device according to claim 1, wherein the relay contact is located in a power supply path from a DC power source to a load.

7. A power supply control method of controlling power supply through a relay contact, wherein a computer executes:
a step of acquiring a first voltage value at a downstream end of the relay contact, if the relay contact is on; and
a step of determining whether or not an abnormality occurs in the relay contact, based on the acquired first voltage value.

8. A computer program for causing a computer to execute:
a step of acquiring a first voltage value at a downstream end of a relay contact through which a current flows, if the relay contact is on; and
a step of determining whether or not an abnormality occurs in the relay contact, based on the acquired first voltage value.

9. The power supply control device according to claim 2, wherein the processing unit is configured to:
acquire a second voltage value at an upstream end of the relay contact; and
acquire the first voltage value, if the relay contact is on and the acquired second voltage value is greater than or equal to a predetermined voltage value.

10. The power supply control device according to claim 3, wherein the processing unit is configured to:
acquire a second voltage value at an upstream end of the relay contact; and
acquire the first voltage value, if the relay contact is on and the acquired second voltage value is greater than or equal to a predetermined voltage value.

11. The power supply control device according to claim 2, wherein the processing unit is configured to:
determine whether or not a switching count that is a number of times the relay contact has been switched on or off is greater than or equal to a count threshold; and
lower the count threshold depending on an abnormality detection count that is a number of times the abnormality has been determined to occur in the relay contact.

12. The power supply control device according to claim 3, wherein the processing unit is configured to:
determine whether or not a switching count that is a number of times the relay contact has been switched on or off is greater than or equal to a count threshold; and
lower the count threshold depending on an abnormality detection count that is a number of times the abnormality has been determined to occur in the relay contact.

13. The power supply control device according to claim 2, wherein the relay contact is located in a power supply path from a DC power source to a load.

14. The power supply control device according to claim 3, wherein the relay contact is located in a power supply path from a DC power source to a load.
